(19) United States
(12) Patent Application Publication
(10) Pub. No.: US 2013/0210217 A1
(43) Pub. Date: Aug. 15, 2013

(54) Precursors for GST Films in ALD/CVD Processes

(71) Applicants: Manchao Xiao, San Diego, CA (US); Iain Buchanan, Stirling (GB); Xinjian Lei, Vista, CA (US)

(72) Inventors: Manchao Xiao, San Diego, CA (US); Iain Buchanan, Stirling (GB); Xinjian Lei, Vista, CA (US)

(73) Assignee: AIR PRODUCTS AND CHEMICALS, INC., Allentown, PA (US)

(21) Appl. No.: 13/572,973

(22) Filed: Aug. 13, 2012

Related U.S. Application Data
(63) Continuation-in-part of application No. 12/355,325, filed on Jan. 16, 2009, now Pat. No. 8,318,252.
(60) Provisional application No. 61/023,989, filed on Jan. 28, 2008.

(51) Int. Cl. H01L 45/00

(52) U.S. Cl. CPC H01L 45/1616
USPC 438/478

(57) ABSTRACT

The present invention is a process of making a germanium-antimony-tellurium alloy (GST) or germanium-bismuth-tellurium (GBT) film using a process selected from the group consisting of atomic layer deposition and chemical vapor deposition, wherein a silylantimony precursor is used as a source of antimony for the alloy film. The invention is also related to making antimony alloy with other elements using a process selected from the group consisting of atomic layer deposition and chemical vapor deposition, wherein a silylantimony or silylbismuth precursor is used as a source of antimony or bismuth.

### CROSS REFERENCE TO RELATED APPLICATIONS

The present patent application is a continuation-in-part of U.S. patent application Ser. No. 12/355,325, filed on Jan. 16, 2009, which, in turn, claims the benefit of priority under 35 U.S.C. §119(e) of U.S. Provisional Patent Application Ser. No. 61/023,989, filed on Jan. 28, 2008.

### BACKGROUND OF THE INVENTION

As an emerging technology, phase change materials attract more and more interest for their applications in manufacturing a new type of highly integrated, nonvolatile, memory devices: phase change random access memory (PRAM). Phase change random acess memory (PRAM) devices are synthesized using materials that undergo a reversible phase change between crystalline and amorphous phases, that have distinctly different resistances. The most commonly used phase change materials are ternary compositions of chalcogenide of group 14 and group 15 elements, such as germanium-antimony-tellurium compounds, commonly abbreviated as GST.

One of the technical hurdles in designing a PRAM cell is that in order to overcome the heat dissipation during the switching of GST materials from crystalline to amorphous states at certain temperatures, a high level of reset current has to be applied. This heat dissipation can be greatly reduced by confining the GST material into contact plugs, that would reduce the reset current needed for the action. To build GST plugs on the substrate, atomic layer deposition (ALD) processes are used to produce films with high conformality and chemical composition uniformity.

Relevant prior art includes:
Sang-Wook Kim, S. Sujith, Bun Yeoul Lee, Chem. Commun., 2006, pp 4811-4813.
Stephan Schulz, Martin Nieger, J. Organometallic Chem., 570, 1998, pp 275-278.
Byung Joon Choi, et al. Chem. Mater. 2007, 19, pp 4387-4389; Byung Joon Choi, et al. J. Electrochem. Soc., 154, pp H318-H324 (2007);
Ranyoung Kim, Hogi Kim, Soongil Yoon, Applied Phys. Letters, 89, pp 102-107 (2006).
Junghyun Lee, Sangjoon Choi, Changsoo Lee, Yoonho Kang, Daeil Kim, Applied Surface Science, 253 (2007) pp 3969-3976.
G. Becker, H. Freudenblum, O. Mundt, M. reti, M. Sachs, Synthetic Methods of Organometallic and Inorganic Chemistry, vol. 3, H. H. Karsch, New York, 1996, p. 193.
Sladek, A., Schmidbaur, H., Chem. Ber. 1995, 128, pp 565-567.

US patents and patent applications:
US 2006/0049447 A1
US 2006/0039192 A1;
US 2006/0072370 A1;
US 2006/0172083 A1;
U.S. Pat. No. 8,148,197;
US 2012/171812 A1; and
U.S. Pat. No. 7,817,464.

### BRIEF SUMMARY OF THE INVENTION

In one aspect, the present invention provides an ALD process for making an antimony-containing film on a surface of a substrate, the process comprising the steps of: introducing into a deposition chamber a germanium alkoxide as a precursor wherein the germanium alkoxide is represented by the formula Ge(OR¹⁴)₄, wherein R¹⁴ is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group, to form a molecular layer of germanium alkoxide on the surface of the substrate; and introducing into the deposition chamber a silylantimony precursor selected from the group consisting of:

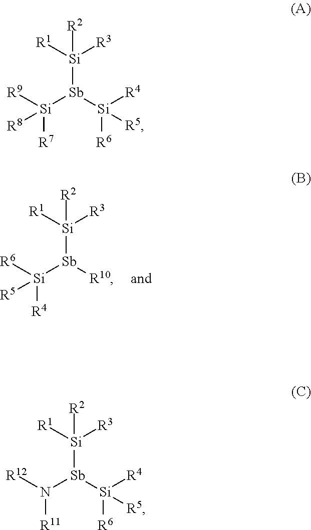

where R¹⁻¹⁰ are individually a hydrogen atom, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group; R¹¹ and R¹² are individually a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group to form an Sb layer on top of the Te layer, wherein the Sb comprises silyl substituents.

In another aspect, the present invention provides an ALD process for making a germanium-bismuth-tellurium alloy film on a surface of a substrate, the process comprising the steps of: introducing into a deposition chamber a germanium alkoxide as a precursor wherein the germanium alkoxide is represented by the formula Ge(OR¹⁴)₄, wherein R¹⁴ is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group, to form a molecular layer of germanium alkoxide on the surface of the substrate; introducing into the deposition chamber a tellurium precursor selected from the group consisting of:

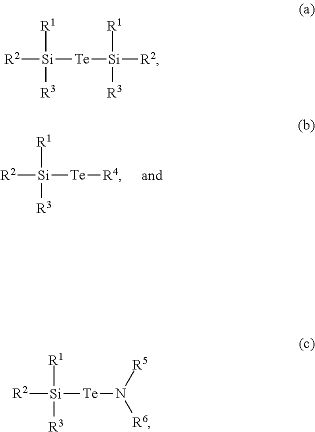

where R¹, R², R³, R⁴, R⁵, and R⁶ are independently hydrogen, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group to react with the germanium alkoxide layer to form a Te layer comprising Te—Ge bonds, wherein the Te comprises silyl substituents; reacting the silyl substituents on the Te to form Te—H bonds with (i) water and/or (ii) an alcohol having the general formula of ROH, where R is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group; introducing into the deposition chamber a silylantimony precursor selected from the group consisting of:

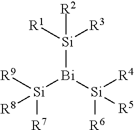

where R¹⁻¹⁰ are individually a hydrogen atom, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group to form an Sb layer on top of the Te layer, wherein the Bi comprises silyl substituents; and reacting the substituents on the Bi to form Bi—H bonds with (i) water and/or (ii) an alcohol having the general formula of ROH, where R is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group.

In yet another aspect, the present invention provides an ALD process for making an antimony- or bismuth-containing film on a surface of a substrate, the process comprising the steps of: Introducing into a deposition chamber a silylantimony or bismuth precursor selected from the group consisting of:

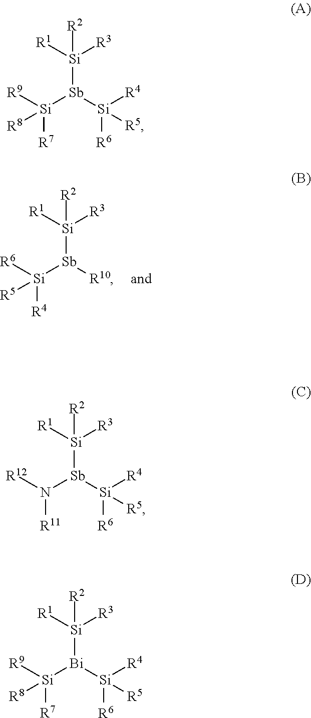

where R¹⁻¹⁰ are individually a hydrogen atom, an alkyl group or alkenyl group with 1 to 10 carbons as chain, branched, or cyclic, or an aromatic group; R¹¹ and R¹² are individually a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group to form a silylantimony monolayer; and introducing into the deposition chamber a second precursor selected from the group consisting of:

M(OR¹³)₃, wherein M=Ga, In, Sb, and Bi; and R¹³ is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group,

M(OR¹³)₃₋ₓLₓ, wherein M=Sb or Bi; L is selected from Cl, Br, I, or mixtures thereof; x is 0, 1 or 2 with a proviso that x cannot be 0 when M=Sb; and R¹³ is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group.

M(OR¹⁴)₄₋ₓLₓ, wherein M is selected from the group consisting of Ge, Sn, Pb; L is selected from Cl, Br, I, or mixtures thereof; x is 0, 1, 2 or 3; R¹⁴ is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group.

M(NR¹⁴R¹⁵)₃₋ₓLₓ wherein M is selected from the group consisting of Sb, Bi, Ga, In; L is selected from Cl, Br, I, or mixtures thereof; x is 1, 2 or 3; R¹⁴ is a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group; and R¹⁵ is selected from the group consisting of hydrogen, a C₁-C₁₀ alkyl group or C₃-C₁₀ alkenyl group, a C₃-C₁₀ cyclic group, a C₃-C₁₀ cyclic alkenyl group, or a C₄-C₁₀ aromatic group, and

M(NR¹⁴R¹⁵)₄₋ₓLₓ wherein M is selected from the group consisting of Ge, Sn, Pb; L is selected from Cl, Br, I, or mixtures thereof; x is 1, 2 or 3; R¹⁴ is a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group; and R¹⁵ is selected from the group consisting of hydrogen, a C₁-C₁₀ alkyl group or C₃-C₁₀ alkenyl group, a C₃-C₁₀ cyclic group, a C₃-C₁₀ cyclic alkenyl group, or a C₄-C₁₀ aromatic group.

### DETAILED DESCRIPTION OF THE INVENTION

The present invention relates to a class of antimony or bismuth precursors, which generate antimony layers in an ALD process. The antimony or bismuth or animony-bismuth alloy layer reacts with subsequently deposited germanium and tellurium layers in ALD cycles to form GST ternary material films, which are suitable for PRAM devices.

GST or GBT materials in PRAM devices are normally deposited in the temperature range of 180°-300° C. It was found that the film deposited at 200° C. has the best chemical and structural properties. The ALD process requires precursors with high chemical reactivity and reaction selectivity. Currently existing precursors, such as dialkyltellium, trialkylantimony, and alkylgermanes do not have the required reactivity at given deposition conditions to be used in ALD cycles. Frequently, plasma is used to promote the deposition.

This invention provides silylantimony compounds as ALD precursors, which react with alcohols or water to generate an antimony layer. With subsequent deposition of germanium and tellurium from tetraminogermanium and organotellurium precursors, a GST or GBT film can be deposited on substrate with high conformality.

The present invention relates to silylantimony or silylbismuth precursors, which generate antimony layers in an ALD process. The antimony or bismuth layer reacts with subsequently deposited germanium and tellurium layers in a plurality of ALD cycles to form GST or GBT ternary material films, which are suitable for PRAM devices. In certain embodiments, this invention discloses several silylantimony precursors with high reactivity and thermal stability, and the chemistries to be used in an ALD process to deposit a GST or GBT film in conjunction with other chemicals.

In other embodiments, this invention provides silylantimony or silylbismuth compounds as ALD precursors, which react with alcohols or water to generate antimony atomic layer. With consequent deposition of germanium and tellurium from tetraminogermanium and tellurium precursor, GST film can be deposited on substrate with high conformality.

In certain embodiments, the antimony or bismuth precursors include trisilylantimony, disilylalkylantimony, disilylantimony, or disilylaminoantimony selected from the group consisting of:

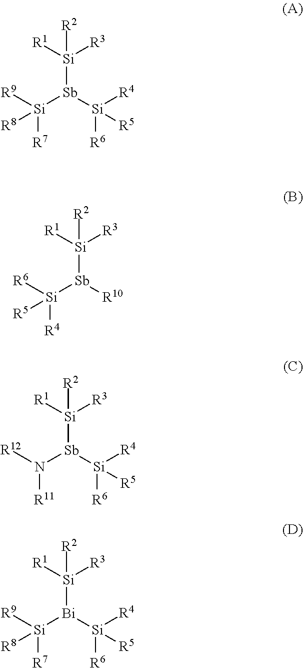

where R¹⁻¹⁰ are individually a hydrogen atom, an alkyl group or alkenyl group with 1 to 10 carbons as chain, branched, or cyclic, or an aromatic group; R¹¹ and R¹² are individually a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group. In certain embodiments, R¹ is a hydrogen atom, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group. Preferably if in structure (A), one of R¹⁻⁹ is aromatic, then the remaining of R¹⁻⁹ on that silicon bearing the aromatic are not both methyl.

Throughout the description, the term “alkyl” denotes a linear, or branched functional group having from 1 to 10 or 1 to 6 carbon atoms. Exemplary alkyl groups include, but are not limited to, methyl, ethyl, propyl, isopropyl, butyl, isobutyl, sec-butyl, tert-butyl, pentyl, iso-pentyl, tert-pentyl, hexyl, iso-hexyl, and neo-hexyl. In certain embodiments, the alkyl group may have one or more functional groups such as, but not limited to, an alkoxy group, a dialkylamino group or combinations thereof, attached thereto. In other embodiments, the alkyl group does not have one or more functional groups attached thereto. The term “cyclic alkyl” denotes a cyclic functional group having from 3 to 10 or from 4 to 10 carbon atoms or from 5 to 10 carbon atoms. Exemplary cyclic alkyl groups include, but are not limited to, cyclobutyl, cyclopentyl, cyclohexyl, and cyclooctyl groups. The term “aromatic” denotes an aromatic cyclic functional group having from 4 to 10 carbon atoms or from 6 to 10 carbon atoms. Exemplary aryl groups include, but are not limited to, phenyl, benzyl, chlorobenzyl, tolyl, and o-xylyl. The term “alkenyl group” denotes a group which has one or more carbon-carbon double bonds and has from 2 to 10 or from 2 to 6 or from 2 to 4 carbon atoms.

Exemplary trisilylantimony or trisilylbimuth precursors include, for example, tri(trimethylsilyl)antimony, tri(triethylsilyl)antimony, and tri(tert-butyldimethylsilyl)antimony, tri(trimethylsilyl)bismuth, tri(triethylsilyl)bismuth, and tri(tert-butyldimethylsilyl)bismuth, tris(dimethylsilyl)antimony.

Silylantimony or silylbismuth compounds are highly reactive with alcohols or water. The reaction generates elemental antimony or bismuth at low temperature:

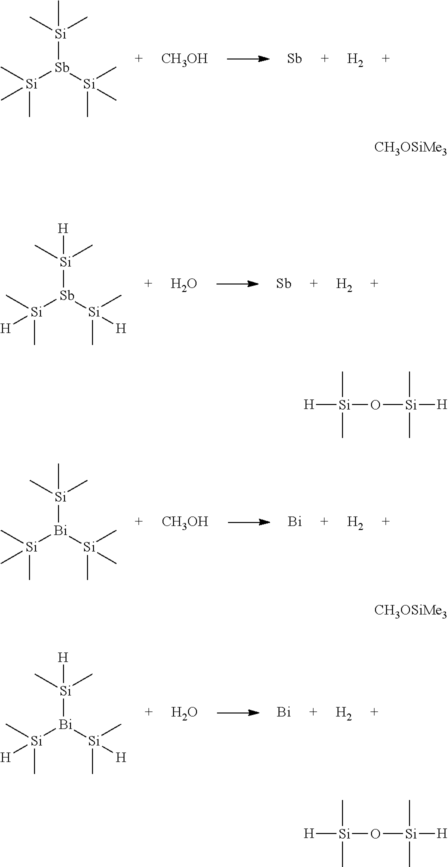

In other embodiments of the present invention, metallic antimony or antimony alloy can be deposited by reacting such silylantimony or silylbismuth compounds with metal compound alkoxides and/or mixed halide and alkoxide compounds. A metalalkoxide includes compounds represented by the formula M(OR¹³)₃, wherein M=Ga, In, Sb, and Bi; R¹³ is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group. A mixed halide and alkoxide metal compound includes compounds represented by the formula M(OR¹³)₃₋ₓLₓ, wherein M=Ga, In, Sb, and Bi; L is selected from Cl, Br, I, or mixtures thereof; x is 1 or 2; and R¹³ is the same as defined above. Example of such compounds include, for example, SbCl(OMe)₂, SbCl₂(OMe), SbBr(OMe)₂, SbBr₂(OMe), Sbl(OMe)₂, SbCl(OEt)₂, SbCl₂(OEt), SbCl(OPrⁱ)₂, SbCl₂(OPrⁱ), BiCl(OMe)₂, BiCl₂(OMe), BiCl(OEt)₂, BiCl₂(OEt), BiCl(OPrⁱ)₂, BiCl₂(OPrⁱ).

These reactions can take place at temperature range of room temperature to 400° C. as demonstrated below.

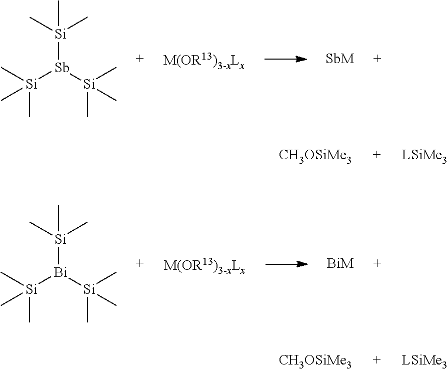

In an ALD process, the silylantimony precursors, alcohols, germanium and tellurium precursors, such as Ge(OMe)₄ and (Me₃Si)₂Te (wherein “Me” is methyl) are introduced to a deposition chamber in a cyclic manner by vapor draw or direct liquid injection (DLI). The deposition temperature is preferably between room temperature and 400° C.

The ALD reaction to deposit GBT films can be illustrated by the following scheme:

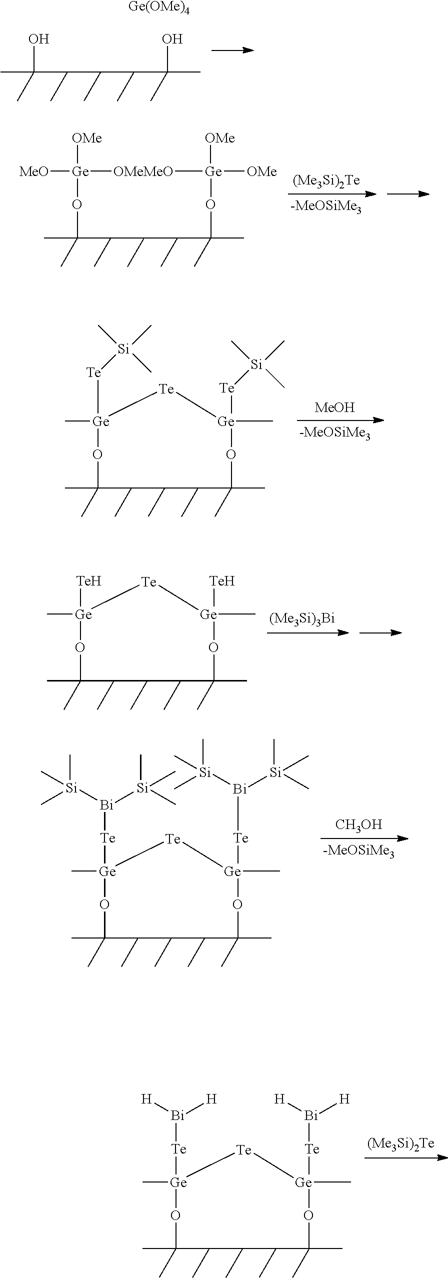

Step 1. Tetrakis(methoxy)germane is introduced and forms a molecular layer of alkoxygermane on the surface of the substrate.

Step 2. Hexamethyldisilyltellurium reacts with aminogermane layer to form Te—Ge bonds with elimination of dimethylaminotrimethylsilane. A Te layer with silyl substituents is formed.

Step 3. Methanol reacts with remaining silyl groups on the tellurium layer to form Te—H bonds and a volatile byproduct, methoxytrimethylsilane, which is removed by purge.

Step 4. Tris(trimethylsilyl)antimony is introduced and forms an antimony layer on the top of the tellurium layer.

Step 5. Methanol reacts with the remaining silyl groups on the antimony layer to form Sb—H bonds and a volatile byproduct, methoxytrimethylsilane, which is removed by purge.

Step 6. Hexamethyldisilyltellurium is introduced again and forms a tellurium layer.

Step 7. Methanol is introduced again to remove silyl groups on the tellurium.

Another ALD reaction can be illustrated by the following scheme for depositing Ge—Te—Ge—Sb or Ge—Te—Ge—Bi films:

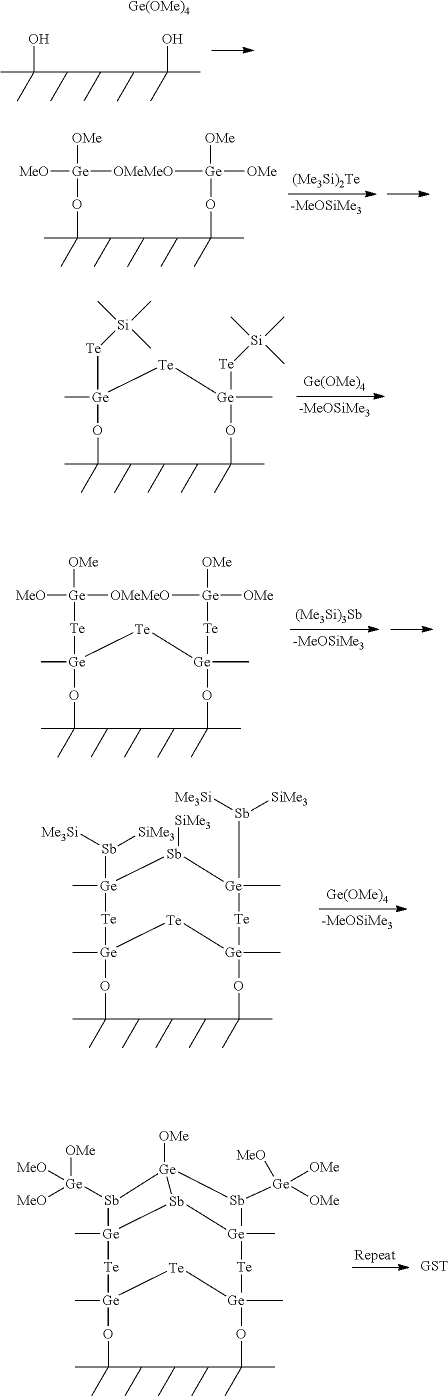

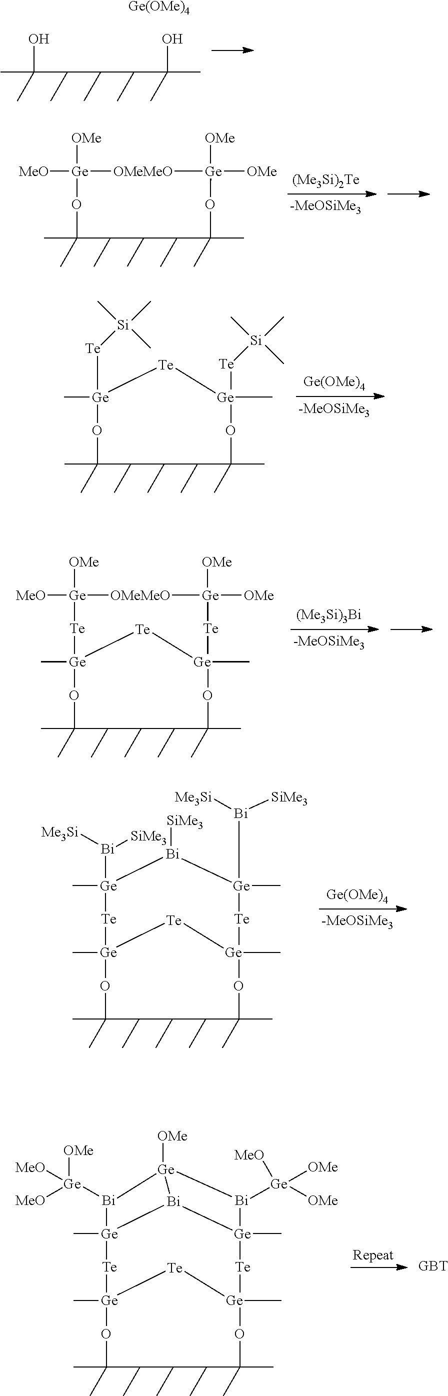

Step 1. Tetrakis(methoxy)germane is introduced and forms a molecular layer of alkoxygermane on the surface of the substrate.

Step 2. Hexamethyldisilyltellurium reacts with alkoxygermane layer to form Te—Ge bonds with elimination of methoxytrimethylsilane. A Te layer with silyl substituents is formed.

Step 3. Tetrakis(methoxy)germane reacts with remaining silyl groups on the layer to form Te—Ge bonds with silylantimony or silylbismuth with elimination of methoxytrimethylsilane. A Ge layer with methoxy substituents is formed.

Step 4. Tris(trimethylsilyl)antimony or tris(trimethylsilyl)bismuth is introduced to form an antimony layer with silyl substituents on the top of the germainium layer via elimination of methoxytrimethylsilane.

Step 5. Tetrakis(methoxy)germane reacts with remaining silyl groups on the Sb or Bi layer to form Sb—Ge or Bi—Ge bonds, generating a Ge layer with methoxy substituents is formed.

An ALD cycle is then repeated, potentially many times, until the desired film thickness is achieved. The next cycle starts with Step 1, again, etc. In another embodiment, step 2 and step 4 can be switched, i.e., depending on whether Ge—Sb—Ge—Te or Ge—Bi—Ge—Te films are to be deposited.

In certain embodiments, the silylantimony or silylbismuth compounds used in this process are selected from the group consisting of:

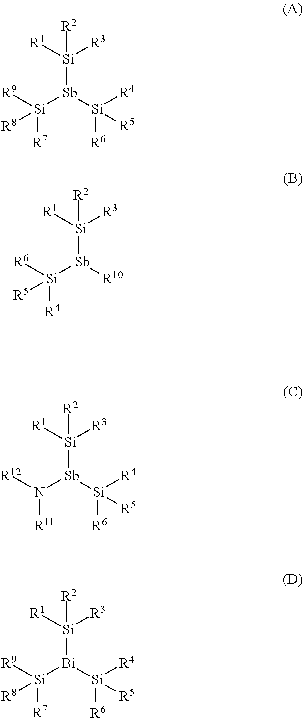

where R¹⁻¹⁰ are individually a hydrogen atom, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group. In certain embodiments, R¹ is a hydrogen atom, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group. R¹¹ and R¹² are individually a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group. Preferably if in structure (A), one of R¹⁻⁹ is aromatic, then the remaining of R¹⁻⁹ on that silicon bearing the aromatic are not both methyl. Further, preferably, if in structure (A) any of R¹⁻⁹ are C¹⁻³ or phenyl then not all of R¹⁻⁹ can be the same.

Alkoxygermanes used in this process have the general formula:

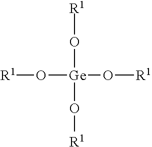

where R¹ is a hydrogen atom, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group.

In yet another embodiments of the present invention, GST films can be formed by employing a germanium compound as a precursor wherein the germanium compound having both halide and alkoxy ligand is represented by the formula Ge(OR¹⁴)₄₋ₓLₓ, wherein L is selected from Cl, Br, I, or mixtures thereof; x is 0, 1, 2 or 3; R¹⁴ is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group. The germanium compound precursor can be reacted with, for example, silylantimony, silylbismuth, or silyltelluride in the same manner as M(OR¹³)₃₋ₓLₓ as described above. Examples of germanium compound having both halide and alkoxy ligand include, for example, GeCl(OMe)₃, GeCl₂(OMe)₂, GeCl₃(OMe), GeCl(OEt)₃, GeCl₂(OEt)₂, GeCl₃(OEt), GeCl(OPrⁿ)₃, GeCl₂(OPrⁿ))₂, GeCk₃(OPrⁿ), GeCl(OPrⁱ)₃, GeCl₂(OPrⁱ))₂, GeCl₃(OPrⁱ), GeCl(OBu^{t})₃, GeCl₂(OBu^{t})₂, and GeCl₃(OBu^{t}), wherein OBu^{t} is tert-butyl alkoxy, OPrⁿ is n-propoxy, and OPrⁱ is iso-propoxy. Such compounds are preferably thermally stable and have bulky alkoxy groups which prevents disportionation reactions.

The silyltellurium precursors can include disilyltellurium, silylalkyltellurium, or silylaminotellurium selected from the group consisting of:

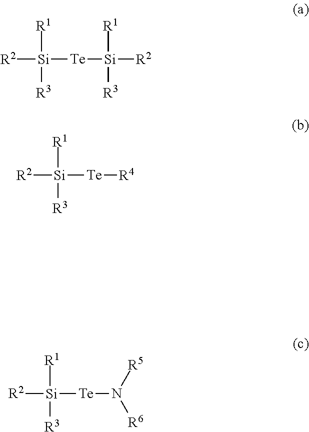

where R¹, R², R³, R⁴, R⁵, and R⁶ are independently hydrogen, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group. Exemplary disilytellurium precursors include, for example, bis(trimethylsilyl)tellurium, bis(triethylsilyl)tellurium, and bis(tert-butyldimethylsilyl)tellurium.

In other embodiments of the present invention, antimony or bismuth-containing films can be made by reacting a silylantimony or silylbismuth compound with mixed amino and halide compounds with a formula of M(NR¹⁴R¹⁵)₃₋ₓLₓ or M(NR¹⁴R¹⁵)₄₋ₓLₓ wherein M is selected from the group consisting of Sb, Bi, Ga, In, Ge, Sn, Pb; L is selected from Cl, Br, I, or mixtures thereof; x is 1, 2 or 3; R¹⁴ is a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group; and R¹⁵ is selected from the group consisting of hydrogen, a C₁-C₁₀ alkyl group or C₃-C₁₀ alkenyl group, a C₃-C₁₀ cyclic group, a C₃-C₁₀ cyclic alkenyl group, or a C₄-C₁₀ aromatic group.

For example, germanium compounds having both amino and halide ligands that are suitable for use in the process of the present invention are described in V. N. Khrustalev et al. “New Stable Germylenes, Stannylenes, and related compounds. 8. Amidogermanium(II) and -tin(II) chlorides R₂NE14Cl (E14=Ge, R=Et; Sn, R=Me) Revealing New Structural Motifs”, Appl. Organometal. Chem., 2007; 21: 551-556, which is incorporated herein by reference. An example of such compounds is [GeCl(NMe₂)]₂.

Antimony compounds having mixed amino and halide ligands suitable for use in the process of the present invention include those disclosed in Ensinger, U. and A. Schmidt (1984), “Dialkylaminostibines. Preparation and spectra” Z. Anorg. Allg. Chem. FIELD Full Journal Title: Zeitschrift fuer Anorganische und Allgemeine Chemie 514: 137-48; and Ensinger, U., W. Schwarz, B. Schrutz, K. Sommer and A. Schmidt (1987) “Methoxostibines. Structure and vibrational spectra.” Z. Anorg. Allg. Chem. FIELD Full Journal Title: Zeitschrift fuer Anorganische und Allgemeine Chemie 544: 181-91, each of which is incorporated herein by reference in its entirety. Examples of such compounds include, for example, Cl₂SbNMe₂ (I), Cl₂SbNMeEt (II), Cl₂SbNEt₂ (III), ClSb[NMe₂]₂ (IV), CISb[NMeEt]₂ (V), CISb[NEt₂]₂ (VI), Ga(NMe₂)₂C1, and Ga(NMe₂)Cl₂,

Indium compounds suitable for use in the process of the present invention include those disclosed by Frey, R., V. D. Gupta and G. Linti (1996). “Monomeric bis and tris(amides) of indium”622(6): 1060-1064; Carmalt, C. J. and S. J. King (2006). “Gallium(III) and indium(III) alkoxides and aryloxides.” Coordination Chemistry Reviews 250(5-6): 682-709; Carmalt, C. J. (2001). “Amido compounds of gallium and indium.” Coordination Chemistry Reviews 223(1): 217-264; Frey, R., V. D. Gupta and G. Linti (1996). “Monomeric bis and tris(amides) of indium.” Monomere bis- und tris(amide) des indiums 622(6): 1060-1064; Suh, S. and D. M. Hoffman (2000). “General Synthesis of Homoleptic Indium Alkoxide Complexes and the Chemical Vapor Deposition of Indium Oxide Films.” Journal of the American Chemical Society 122(39): 9396-9404. Examples of such compounds include, for example, [In(OCH₂CH₂NMe₂)₃]₂, [In(μ-O^{t}Bu)(O^{t}Bu)₂]₂, [In(OCMe₂Et)₂(μ-OCMe₂Et)]₂, In[N(^{t}Bu)(SiMe₃)]₃, In(TMP)₃ (TMP=2,2,6,6-tetramethylpiperidino), and In(N(cyclohexyl)₂)₃.

Alcohols used in this process have the general formula:

ROH

where R is an alkyl group or alkenyl group with 1 to 10 carbons in linear, branched, or cyclic form or an aromatic group. For example, R can be a C₁-C₁₀ alkyl group, C₂-C₁₀ alkenyl group, a C₃-C₁₀ cyclic alkyl group, a C₂-C₁₀ cyclic alkenyl group, or a C₄-C₁₀ aromatic group. In certain embodiments, methanol is preferred.

### EXAMPLES

### Example 1

### Synthesis of Tris(trimethylsilyl)antimony

1.22 g (0.01 mol) of 200 mesh antimony powder, 0.72 g (0.03 mol) of lithium hydride, and 40 ml of tetrahydrofuran (THF) were placed in a 100 ml flask. With stirring, the mixture was refluxed for 4 hours. All of the black powder constituting antimony disappeared, and a muddy colored precipitate was formed. Then, the mixture was cooled down to −20° C.; 3.3 g (0.03 mol) of trimethylchlorosilane was added. The mixture was allowed to warm up to room temperature. After stirring for 4 hours, the mixture was filtered under inert atmosphere. The solvent was removed by distillation. Tris(trimethylsilyl)antimony was purified by vacuum distillation.

### Example 2

### Synthesis of Tris(dimethylsilyl)antimony

1.22 g (0.01 mol) of 200 mesh antimony powder, 0.72 g (0.03 mol) of lithium hydride, and 40 ml of tetrahydrofuran (THF) were placed in a 100 ml flask. With stirring, the mixture was refluxed for 4 hours. All of the black powder constituting antimony disappeared, and a muddy colored precipitate was formed. Then, the mixture was cooled down to −20° C.; 2.83 g (0.03 mol) of diimethylchlorosilane was added. The mixture was allowed to warm up to room temperature. After stirring for 4 hours, the mixture was filtered under inert atmosphere. The solvent was removed by distillation. Tris(dimethylsilyl)antimony was purified by vacuum distillation.

### Example 3

### Synthesis of Tris(dimethylsilyl)antimony

3.65 g (0.03 mol) of 200 mesh antimony powder, 2.07 g (0.09 mol) of sodium, 1.15 g (0.009 mol) of naphthalene, and 50 ml of THF were placed in a 100 ml flask. The mixture was stirred at room temperature for 24 hours. All of the black powder constituting antimony and sodium disappeared, and a muddy colored precipitate was formed. Then, the mixture was cooled down to −20° C.; 8.51 g (0.09 mol) of dimethylchlorosilane was added. The mixture was allowed to warm up to room temperature. After stirring for 4 hours, the mixture was filtered under inert atmosphere. The solvent was removed by distillation. Tris(dimethylsilyl)antimony was purified by vacuum distillation.

### Example 4

### Synthesis of Tris(trimethylsilyl)bismuth (Prophetic)

6.27 g (0.03 mol) of 200 mesh bismuth powder, 2.07 g (0.09 mol) of sodium, 1.15 g (0.009 mol) of naphthalene, and 50 ml of THF is placed in a 100 ml flask. The mixture is stirred at room temperature for 24 hours. All of the black powder constituting antimony and sodium disappears, and a muddy colored precipitate forms. Then, the mixture is cooled down to −20° C.; 9.77 g (0.09 mol) of trimethylchlorosilane is added. The mixture is allowed to warm up to room temperature. After stirring for 4 hours, the mixture is filtered under inert atmosphere. The solvent is removed by distillation. Tris(trmethylsilyl)bismuth can be purified by vacuum distillation.

### Example 5

### Generation of Antimony Film

0.05 g of tris(dimethylsilyl)antimony was placed on the bottom of a 100 ml pyrex glass flask filled with nitrogen and fitted with a rubber septem. 0.1 g of methanol was added slowly with a syringe. A shiny black film started to deposit inside the glass wall of the flask. After a few minutes, the entire flask interior was coated with a dark gray/black antimony film.

### Example 6

### Synthesis of Germanium Bismuthide (Prophetic)

0.43 g (0.001 mol) tris(trimethylsilyl)bismuth is dissolved in 6 ml of acetonitrile. To the solution, 0.12 g tetramethoxygermane is added at room temperature. The reaction is exo-thermic. A black precipitate forms immediately. The precipitate is filtered out and washed with THF, and dried in air. Energy Dispersive X-ray Analysis (EDX) in conjunction with Scanning Electron Microscopy (SEM) can be used to study the black solid precipitate. The results will indicate that the black solid is a composition of germanium and bithmuth. Germanium bithmuthide is insoluble in organic solvents.

### Example 7

### Synthesis of Indium Antimonide (Prophetic)

0.38 g (0.001 mol) indium tri-t-pentoxide is dissolved in 6 ml of acetonitrile. To the solution, 0.34 g (0.001 mol) Tris(trimethylsilyl)antimony is added at room temperature. The reaction is exo-thermic. A black precipitate is formed immediately. The precipitate is filtered out and washed with THF, and dried in air. Energy Dispersive X-ray Analysis (EDX) in conjunction with Scanning Electron Microscopy (SEM) can be used to study the black solid precipitate. The results will indicate that the black solid is a composition of indium and antimony. Indium antimonide is insoluble in organic solvents.

### Example 8

### Synthesis of Bismuth Antimonide (Prophetic)

0.34 g (0.001 mol) bismuth triethoxide is dissolved in 6 ml of acetonitrile. To the solution, 0.34 g (0.001 mol) Tris(trimethylsilyl)antimony is added at room temperature. The reaction is exo-thermic. A black precipitate is formed immediately. The precipitate is filtered out and washed with THF, and dried in air. Energy Dispersive X-ray Analysis (EDX) in conjunction with Scanning Electron Microscopy (SEM) can be used to study the black solid precipitate. The results indicated that the black solid is a composition of antimony and bitsmuth. Bismuth antimonide is insoluble in organic solvents.

### Example 9

### Deposition of GeBi Films in ALD Reactor (Prophetic)

Deposition of GeBi film using atomic layer deposition (ALD) technique including the following steps:
a) Substrates to be deposited films on are loaded to an ALD reactor;
b) The reactor is flashed with N₂ and pumped down to low pressure of less than 1 torr and heated up to a temperature at which film deposition is performed;
c) A fixed flow rate of the vapor of silylbismuth compound as Bi precursor is introduced to the reactor. The reactor is saturated with this vapor for a short fixed time (typical less than 5 seconds), and then pumped down to 1 torr, followed by flashing with N₂;
d) A fixed flow rate of the vapor of alkoxygermane compound as Ge precursor is introduced to the reactor. The reactor is saturated with this vapor for a short fixed time (typical less than 5 seconds), and then pumped down to 1 torr, followed by flashing with N₂; and
   Steps c) to d) are repeated until a desired thickness of the film is achieved. In another example, alkoxygermane compound can be introduced in step c) while silylbismuth compound is introduced in step d).

With the deposition chemistry, highly conformal GeBi films can be deposited on the surface of substrate materials such as silicon, silicon oxide, silicon nitride, titanium nitride. The process temperature range could be from room temperature to 400° C.

### Example 10

### Deposition of Sb Films in ALD Reactor

Deposition of antimony film using atomic layer deposition (ALD) technique including the following steps:
a) Substrates to be deposited films on are loaded to an ALD reactor;
b) The reactor is flashed with N₂ and pumped down to low pressure of less than 1 torr and heated up to a temperature at which film deposition is performed;
c) A fixed flow rate of the vapor of trisilylantimony compound is introduced to the reactor. The reactor is saturated with this vapor for a short fixed time (typical less than 5 seconds), and then pumped down to 1 torr, followed by flashing with N₂;
d) A fixed flow rate of the vapor of alkoxyantimony compound is introduced to the reactor. The reactor is saturated with this vapor for a short fixed time (typical less than 5 seconds), and then pumped down to 1 torr, followed by flashing with N₂; and
   Steps c) to d) are repeated until a desired thickness of the film is achieved. In another example, alkoxygermane compound can be introduced in step c) while trisilylbismuth compound is introduced in step d).

With the deposition chemistry, highly conformal antimony films can be deposited on the surface of substrate materials such as silicon, silicon oxide, silicon nitride, titanium nitride. The process temperature range could be from room temperature to 400° C.

### Example 11

### Deposition of GeSbTe Films in ALD Reactor

Deposition of GeBi film using atomic layer deposition (ALD) technique including the following steps:
a) Substrates to be deposited films on are loaded to an ALD reactor;
b) The reactor is flashed with N₂ and pumped down to low pressure of less than 1 torr and heated up to a temperature at which film deposition is performed;
c) A fixed flow rate of the vapor of alkoxygermane compound as Ge precursor is introduced to the reactor. The reactor is saturated with this vapor for a short fixed time (typical less than 5 seconds), and then pumped down to 1 torr, followed by flashing with N₂; and
d) A fixed flow rate of the vapor of disilyltellurium compound as Te precursor is introduced to the reactor. The reactor is saturated with this vapor for a short fixed time (typical less than 5 seconds), and then pumped down to 1 torr, followed by flashing with N₂;
e) A fixed flow rate of the vapor of alkoxygermane compound as Ge precursor is introduced to the reactor. The reactor is saturated with this vapor for a short fixed time (typical less than 5 seconds), and then pumped down to 1 torr, followed by flashing with N₂;
f) A fixed flow rate of the vapor of trisilylantimony compound as Sb precursor is introduced to the reactor. The reactor is saturated with this vapor for a short fixed time (typical less than 5 seconds), and then pumped down to 1 torr, followed by flashing with N₂
   Steps teps c) to f) are repeated until a desired thickness of the film is achieved.

With the deposition chemistry, highly conformal GeSbTe films can be deposited on the surface of substrate materials such as silicon, silicon oxide, silicon nitride, titanium nitride. The process temperature range could be from room temperature to 400° C.

### Example 12

### Deposition of GeBiTe Films in ALD Reactor

Deposition of GeBiTe film using atomic layer deposition (ALD) technique including the following steps:
a) Substrates to be deposited films on are loaded to an ALD reactor;
b) The reactor is flashed with N₂ and pumped down to low pressure of less than 1 torr and heated up to a temperature at which film deposition is performed;
c) A fixed flow rate of the vapor of alkoxygermane compound as Ge precursor is introduced to the reactor. The reactor is saturated with this vapor for a short fixed time (typical less than 5 seconds), and then pumped down to 1 torr, followed by flashing with N₂; and
d) A fixed flow rate of the vapor of disilyltellurium compound as Te precursor is introduced to the reactor. The reactor is saturated with this vapor for a short fixed time (typical less than 5 seconds), and then pumped down to 1 torr, followed by flashing with N₂;
e) A fixed flow rate of the vapor of alkoxygermane compound as Ge precursor is introduced to the reactor. The reactor is saturated with this vapor for a short fixed time (typical less than 5 seconds), and then pumped down to 1 torr, followed by flashing with N₂;
f) A fixed flow rate of the vapor of trisilylbismuth compound as Bi precursor is introduced to the reactor. The reactor is saturated with this vapor for a short fixed time (typical less than 5 seconds), and then pumped down to 1 torr, followed by flashing with N₂
   Steps c) to f) are repeated until a desired thickness of the film is achieved.

With the deposition chemistry, highly conformal GeSbTe films can be deposited on the surface of substrate materials such as silicon, silicon oxide, silicon nitride, titanium nitride. The process temperature range could be from room temperature to 400° C.

1. An ALD process for making an antimony-containing film on a surface of a substrate, the process comprising the steps of:
introducing into a deposition chamber a germanium alkoxide as a precursor wherein the germanium alkoxide is represented by the formula Ge(OR¹⁴)₄, wherein R¹⁴ is a C₁-C₁₀ alkyl group, C₂-C₁₀ alkenyl group, a C₃-C₁₀ cyclic alkyl group, a C₃-C₁₀ cyclic alkenyl group, or a C₄-C₁₀ aromatic group, to form a molecular layer of germanium alkoxide on the surface of the substrate; and
introducing into the deposition chamber a silylantimony precursor selected from the group consisting of: 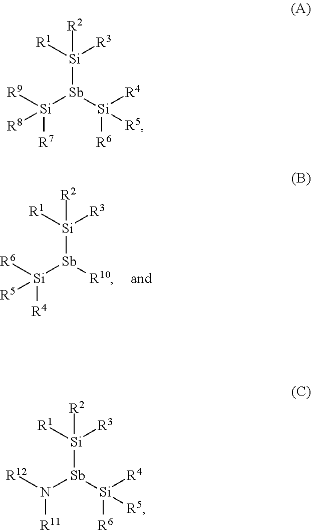
where R¹⁻¹⁰ are individually a hydrogen atom, a C₁-C₁₀ alkyl group, C₂-C₁₀ alkenyl group, a C₃-C₁₀ cyclic alkyl group, a C₃-C₁₀ cyclic alkenyl group, or a C₄-C₁₀ aromatic group; R¹¹ and R¹² are individually an a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group to form an Sb layer on top of the Te layer, wherein the Sb comprises silyl substituents.

2. The process of claim 1 wherein the silylantimony precursor is selected from the group consisting of tris(trimethylsilyl)antimony, tris(triethylsilyl)antimony, and tris(tert-butyldimethylsilyl)antimony, tris(dimethylsilyl)antimony.

3. The process of claim 1 wherein the steps are repeated in sequence.

4. The process of claim 1 wherein the temperature of the deposition chamber is between from room temperature to 400° C.

5. An ALD process for making a germanium-bismuth-tellurium alloy film on a surface of a substrate, the process comprising the steps of:
introducing into a deposition chamber a germanium alkoxide as a precursor wherein the germanium alkoxide is represented by the formula Ge(OR¹⁴)₄, wherein R¹⁴ is a C₁-C₁₀ alkyl group, C₂-C₁₀ alkenyl group, a C₃-C₁₀ cyclic alkyl group, a C₃-C₁₀ cyclic alkenyl group, or a C₄-C₁₀ aromatic group, to form a molecular layer of germanium alkoxide on the surface of the substrate;
introducing into the deposition chamber a tellurium precursor selected from the group consisting of: 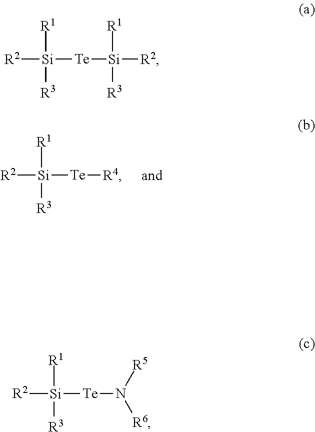
where R¹, R², R³, R⁴, R⁵, and R⁶ are independently hydrogen, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group to react with the germanium alkoxide layer to form a Te layer comprising Te—Ge bonds, wherein the Te comprises silyl substituents;
reacting the silyl substituents on the Te to form Te—H bonds with (i) water and/or (ii) an alcohol having the general formula of ROH, where R is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group;
introducing into the deposition chamber a silylantimony precursor selected from the group consisting of: 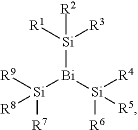
where R¹⁻¹⁰ are individually a hydrogen atom, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group to form an Sb layer on top of the Te layer, wherein the Bi comprises silyl substituents; and
reacting the substituents on the Bi to form Bi—H bonds with (i) water and/or (ii) an alcohol having the general formula of ROH, where R is a C₁-C₁₀ alkyl group, C₂-C₁₀ alkenyl group, a C₃-C₁₀ cyclic alkyl group, a C₂-C₁₀ cyclic alkenyl group, or a C₄-C₁₀ aromatic group.

6. The process of claim 5 wherein the silylbismuth precursor is selected from the group consisting of tris(trimethylsilyl)bismuth, tris(triethylsilyl)bismuth, tris(tert-butyldimethylsilyl)bismuth, and tris(dimethylsilyl)bismuth.

7. The process of claim 5 wherein the steps are repeated in sequence.

8. The process of claim 5 wherein the temperature of the deposition chamber is from room temperature to 400° C.

9. The process of claim 5 wherein the alcohol is methanol.

10. An ALD process for making an antimony- or bismuth-containing film on a surface of a substrate, the process comprising the steps of:
Introducing ino a deposition chamber a silylantimony or bismuth precursor selected from the group consisting of: 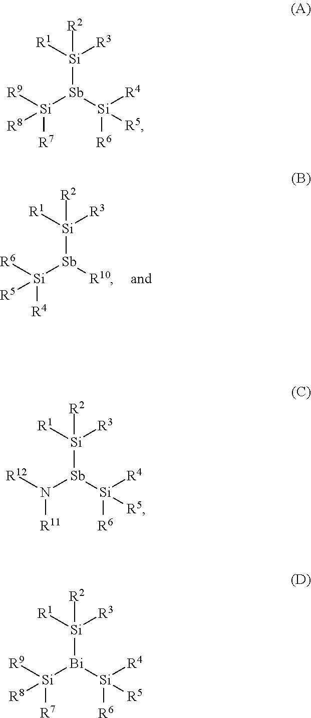
where R¹⁻¹⁰ are individually a hydrogen atom, an alkyl group or alkenyl group with 1 to 10 carbons as chain, branched, or cyclic, or an aromatic group; R¹¹ and R¹² are individually a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group to form a silylantimony monolayer; and
introducing into the deposition chamber a second precursor selected from the group consisting of:
(a) M(OR¹³)₃, wherein M=Ga, In, Sb, and Bi; and R¹³ is a C₁-C₁₀ alkyl group, C₂-C₁₀ alkenyl group, a C₃-C₁₀ cyclic alkyl group, a C₃-C₁₀ cyclic alkenyl group, or a C₄-C₁₀ aromatic group,
(b) M(OR¹³)₃₋ₓLₓ, wherein M=Sb or Bi; L is selected from Cl, Br, I, or mixtures thereof; x is 0, 1 or 2 with a proviso that x cannot be 0 when M=Sb; and R¹³ is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group,
(c) M(OR¹⁴)₄₋ₓLₓ, wherein M is selected from the group consisting of Ge, Sn, Pb; L is selected from Cl, Br, I, or mixtures thereof; x is 0, 1, 2 or 3; R¹⁴ is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group
(d) M(NR¹⁴R¹⁵)₃₋ₓLₓ wherein M is selected from the group consisting of Sb, Bi, Ga, In; L is selected from Cl, Br, I, or mixtures thereof; x is 1, 2 or 3; R¹⁴ is a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group; and R¹⁵ is selected from the group consisting of hydrogen, a C₁-C₁₀ alkyl group or C₃-C₁₀ alkenyl group, a C₃-C₁₀ cyclic group, a C₃-C₁₀ cyclic alkenyl group, or a C₄-C₁₀ aromatic group, and
(e) M(NR¹⁴R¹⁵)₄₋ₓLₓ wherein M is selected from the group consisting of Ge, Sn, Pb; L is selected from Cl, Br, I, or mixtures thereof; x is 1, 2 or 3; R¹⁴ is a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group; and R¹⁵ is selected from the group consisting of hydrogen, a C₁-C₁₀ alkyl group or C₃-C₁₀ alkenyl group, a C₃-C₁₀ cyclic group, a C₃-C₁₀ cyclic alkenyl group, or a C₄-C₁₀ aromatic group.

11. The process of claim 6 wherein the silylantimony precursor is selected from the group consisting of tris(trimethylsilyl)antimony, tris(triethylsilyl)antimony, tris(tert-butyldimethylsilyl)antimony, and tris(dimethylsilyl)antimony.

12. The process of claim 6 wherein the silylbismuth precursor is tris(trimethylsilyl)bismuth.

13. The process of claim 6 wherein the steps are repeated in sequence.

14. The process of claim 6 wherein the temperature of the deposition chamber is from room temperature to 400° C.

15. The process of claim 6 wherein the second precursor is selected from the group consisting of SbCl(OMe)₂, SbCl₂(OMe), SbBr(OMe)₂, SbBr₂(OMe), SbI(OMe)₂, SbCl(OEt)₂, SbCl₂(OEt), SbCl(OPrⁱ)₂, SbCl₂(OPrⁱ), BiCl(OMe)₂, BiCl₂(OMe), BiCl(OEt)₂, BiCl₂(OEt), BiCl(OPrⁱ)₂, BiCl₂(OPrⁱ), Cl₂SbNMeEt (II), Cl₂SbNEt₂ (III), ClSb[NMe₂]₂ (IV), ClSb[NMeEt]₂ (V), ClSb[NEt₂]₂ (VI), Ga(NMe₂)₂Cl, Ga(NMe₂)Cl₂, [In(OCH₂CH₂NMe₂)₃]₂, [In(μ-O^{t}Bu)(O^{t}Bu)₂]₂, [In(OCMe₂Et)₂(m-OCMe₂Et)]₂, In[N(^{t}Bu)(SiMe₃)]₃, In(TMP)₃ (TMP=2,2,6,6-tetramethylpiperidino), and In(N(cyclohexyl)₂)₃.

16. An ALD process for making an germanium-antimony-tellurium (GST) or germanium-bismuth-tellurium (GBT) film film on a surface of a substrate, the process comprising the steps of:
Introducing into a deposition chamber a germainium precursor is selected from Ge(OR¹⁴)₄₋ₓLₓ, wherein L is selected from Cl, Br, I, or mixtures thereof; x is 0, 1, 2 or 3; R¹⁴ is a C₁-C₁₀ alkyl group, C₂-C₁₀ alkenyl group, a C₃-C₁₀ cyclic alkyl group, a C₃-C₁₀ cyclic alkenyl group, or a C₄-C₁₀ aromatic group;
Introducing a silyltelluride precursor selected form the group consisting of The silyltellurium precursors can include disilyltellurium, silylalkyltellurium, or silylaminotellurium selected from the group consisting of: 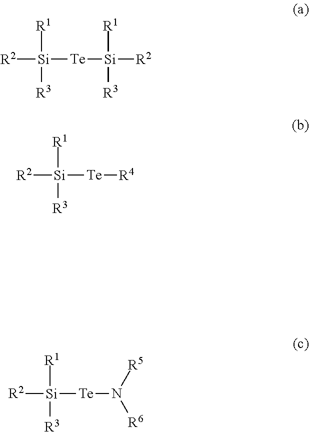
where R¹, R², R³, R⁴, R⁵, and R⁶ are independently hydrogen, a C₁-C₁₀ alkyl group, C₂-C₁₀ alkenyl group, a C₃-C₁₀ cyclic alkyl group, a C₃-C₁₀ cyclic alkenyl group, or a C₄-C₁₀ aromatic group;
Introducing into a deposition chamber a germainium precursor is selected from Ge(OR¹⁴)₄₋ₓLₓ, wherein L is selected from Cl, Br, I, or mixtures thereof; x is 0, 1, 2 or 3; R¹⁴ is a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group;
Introducing into a deposition chamber a silylantimony or silylbismuth precursor selected from the group consisting of: 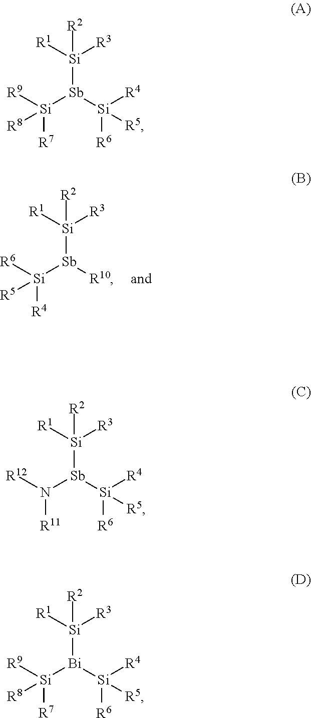
where R¹⁻¹⁰ are individually a hydrogen atom, a C₁-C₁₀ alkyl group or C₂-C₁₀ alkenyl group, a C₃-C₁₀ cyclic alkyl group, a C₃-C₁₀ cyclic alkenyl group, or a C₄-C₁₀ aromatic group; R¹¹ and R¹² are individually a C₁-C₁₀ alkyl group or C₃-C₁₀ alkenyl group, a C₃-C₁₀ cyclic alkyl group, a C₃-C₁₀ cyclic alkenyl group, or a C₄-C₁₀ aromatic group to form a silylantimony or silylbismuth monolayer; and
repeating the steps above until a desired thickness is reached.

17. The process of claim 11 wherein the germainium precursor is selected from the group consisting of Ge(OMe)₄, Ge(OEt)₄, Ge(OPrⁿ)₄, Ge(OPrⁱ)₄, GeCl(OMe)₃, GeCl₂(OMe)₂, GeCl₃(OMe), GeCl(OEt)₃, GeCl₂(OEt)₂, GeCl₃(OEt), GeCl(OPrⁿ)₃, GeCl(OPrⁿ)₃, GeCl₂(OPrⁿ))₂, GeCl₂(OPrⁱ)₂, GeCl₃(OPrⁱ), GeCl(OBu^{t})₃, GeCl₂(OBu^{t}))₂, and GeCl₃(OBu^{t}).

18. The process of claim 11 wherein the silylantimony precursor is selected from the group consisting of tris(trimethylsilyl)antimony, tris(triethylsilyl)antimony, tris(tert-butyldimethylsilyl)antimony, and tris(dimethylsilyl)antimony.

19. The process of claim 11 wherein the silylbismuth precursor is selected from the group consisting of tris(trimethylsilyl)bismuth, tris(triethylsilyl)bismuth, and tris(tert-butyldimethylsilyl)bismuth.

20. The process of claim 11 wherein the disilyltellurium precursor is selected from the group consisting of bis(trimethylsilyl)tellurium, bis(triethylsilyl)tellurium, and bis(tert-butyldimethylsilyl)tellurium.
